(19) United States
(12) Patent Application Publication
(10) Pub. No.: US 2020/0369833 A1
(43) Pub. Date: Nov. 26, 2020

(54) MOISTURE BARRIER FILM, MOISTURE BARRIER DEVICE INCLUDING THE SAME AND METHOD FOR PREPARING MOISTURE BARRIER DEVICE

(71) Applicant: NATIONAL TAIPEI UNIVERSITY OF TECHNOLOGY, Taipei City (TW)

(72) Inventors: Chung-Kuan YANG, Taipei City (TW); Yi-Fan CHEN, Taipei City (TW); Sheng-Tung HUANG, Taipei City (TW); Kun-Li WANG, Taipei City (TW)

(21) Appl. No.: 16/438,251

(22) Filed: Jun. 11, 2019

(30) Foreign Application Priority Data
May 20, 2019 (TW) 108117286

(51) Int. Cl. C08G 77/04; B32B 27/36; B32B 27/28; C08G 77/398; B32B 15/20

(52) U.S. Cl. CPC C08G 77/045; B32B 27/36; B32B 27/283; C08G 77/398; C23C 16/403; B32B 2307/7265; B32B 2307/73; B32B 2307/7246; B32B 2307/412; B32B 15/20

(57) ABSTRACT

A moisture barrier film, a moisture barrier device including the same and a method for preparing the moisture barrier device is provided. The moisture barrier film includes a hydrophobic modifying layer adapted to be formed on a substrate. The hydrophobic modifying layer is formed by solidification of a colloidal solution which includes a product obtained by subjecting a first trialkoxysilane having a hydrophobic group to a hydrolysis and condensation reaction with at least one of a second trialkoxysilane having a reactive group or a tetraalkoxysilane to form a polysilsesquioxane mixture, and subjecting the polysilsesquioxane mixture to modification with a metal source.

### CROSS-REFERENCE TO RELATED APPLICATION

This application claims priority of Taiwanese Patent Application No. 108117286, filed on May 20, 2019.

### FIELD

The present disclosure relates to a barrier film, and more particularly to a moisture barrier film having a water vapor barrier effect. The present disclosure also relates to a moisture barrier device including the moisture barrier film and a method for preparing the same.

### BACKGROUND

With the rapid development of electronic devices, glass substrate, which is heavy and thick, is gradually replaced by a plastic substrate, which is lightweight, thin, and highly flexible. As such, the plastic substrate has been widely utilized for manufacturing flexible electronic devices such as electronic papers, dye-sensitized solar cells, organic photovoltaics, organic light-emitting diodes, and the like.

The flexible electronic devices such as the organic photovoltaics and the organic light-emitting diodes are provided with highly sensitive organic materials and easily oxidizable cathode metals therein. The use of plastic substrates in the flexible electronic devices has disadvantage, that is, a relatively high water vapor transmission rates, which easily allows moisture in the air to penetrate through the plastic substrate and reach the interior of the flexible electronic devices, causing the organic materials and the cathode metals provided therein to be deteriorated and aged, thereby reducing the stability and lifespan of the flexible electronic devices.

In order to extend the lifespan of the flexible electronic devices for industrial applications, a barrier film is usually applied onto the plastic substrate to impart water vapor barrier effect to the plastic substrate, so as to prevent the organic materials and the cathode metals interior of the flexible electronic devices from deteriorating and aging. In addition, a barrier film for blocking water vapor is also required to have a high light transmission property.

### SUMMARY

Therefore, an object of the present disclosure is to provide a moisture barrier film, which can alleviate at least one of the drawbacks of the prior art.

According to the present disclosure, the moisture barrier film is adapted to be formed on a substrate and includes a hydrophobic modifying layer adapted to be proximate to the substrate. The hydrophobic modifying layer is formed by solidification of a colloidal solution which includes a product obtained by subjecting a first trialkoxysilane having a hydrophobic group to a hydrolysis and condensation reaction with at least one of a second trialkoxysilane having a reactive group or a tetraalkoxysilane to form a polysilsesquioxane mixture, and subjecting the polysilsesquioxane mixture to modification with a metal source.

Another object of the present disclosure is to provide a moisture barrier device and a method for preparing the same, which can alleviate at least one of the drawbacks of the prior art.

According to the present disclosure, the moisture barrier device includes a substrate and the abovementioned moisture barrier film disposed on the substrate.

The method for preparing the moisture barrier device includes the steps of:

providing a substrate;

forming a polysilsesquioxane mixture by subjecting a first trialkoxysilane having a hydrophobic group to a hydrolysis and condensation reaction with at least one of a second trialkoxysilane having a reactive group or a tetraalkoxysilane, followed by modifying the polysilsesquioxane mixture with a metal source to obtain a colloidal solution; and

applying the colloidal solution to the substrate and solidifying the colloidal solution, so as to form a hydrophobic modifying layer on the substrate.

### BRIEF DESCRIPTION OF THE DRAWINGS

Other features and advantages of the present disclosure will become apparent in the following detailed description of the embodiments with reference to the accompanying drawings, of which:

FIG. 1 is a schematic view of a first embodiment of a moisture barrier device according to the present disclosure;

FIG. 2 is a schematic view of a second embodiment of a moisture barrier device according to the present disclosure;

FIG. 3 is a schematic view of a third embodiment of a moisture barrier device according to the present disclosure;

FIG. 4 is a schematic view of a fourth embodiment of a moisture barrier device according to the present disclosure;

FIG. 5 is a schematic view of a fifth embodiment of a moisture barrier device according to the present disclosure;

FIG. 6 is a schematic view of a sixth embodiment of a moisture barrier device according to the present disclosure;

FIG. 7 shows light transmittance rates of modifying layers of Preparative Example 1 and Comparative Example 1 at different wavelengths; and

FIG. 8 shows light transmission rates of the moisture barrier films of Example 1 to Example 6.

### DETAILED DESCRIPTION

The present disclosure provides a moisture barrier film that is adapted to be formed on a substrate and that includes a hydrophobic modifying layer adapted to be proximate to the substrate. The hydrophobic modifying layer is formed by solidification of a colloidal solution which includes a product obtained by subjecting a first trialkoxysilane having a hydrophobic group to a hydrolysis and condensation reaction with at least one of a second trialkoxysilane having a reactive group or a tetraalkoxysilane to form a polysilsesquioxane mixture, and subjecting the polysilsesquioxane mixture to modification with a metal source.

In certain embodiments, the polysilsesquioxane mixture is prepared by subjecting the first trialkoxysilane and the second trialkoxysilane to the hydrolysis and condensation reaction. In other embodiments, the polysilsesquioxane mixture is prepared by subjecting the first trialkoxysilane and tetraalkoxysilane to the hydrolysis and condensation reaction. In yet other embodiments, the polysilsesquioxane mixture is prepared by subjecting the first trialkoxysilane, the second trialkoxysilane and the tetraalkoxysilane to the hydrolysis and condensation reaction.

In an exemplary embodiment of the present disclosure, the polysilsesquioxane mixture includes a first polysilsesquioxane and a second polysilsesquioxane. The first polysilsesquioxane is prepared by subjecting the first trialkoxysilane and the second trialkoxysilane to a first hydrolysis and condensation reaction, and the second polysilsesquioxane is prepared by subjecting the first trialkoxysilane and the tetraalkoxysilane to a second hydrolysis and condensation reaction. The first trialkoxysilane for preparing the first polysilsesquioxane and that for preparing the second polysilsesquioxane may be the same or different.

The first trialkoxysilane and the second trialkoxysilane may be reacted in a molar ratio ranging from 1:1 to 7:3 to form the first polysilsesquioxane. In an exemplary embodiment, the first trialkoxysilane and the second trialkoxysilane are reacted in a molar ratio of 6:4.

The first trialkoxysilane and the tetraalkoxysilane may be reacted in a molar ratio ranging from 3:7 to 1:1 to form the second polysilsesquioxane. In an exemplary embodiment, the first trialkoxysilane and the tetraalkoxysilane are reacted in a molar ratio of 3:7.

In certain embodiments, the hydrophobic group of the first trialkoxysilane includes a phenyl group. In certain embodiments, the first trialkoxysilane has an alkoxy group with a carbon number ranging from 1 to 2. In an exemplary embodiment, the first trialkoxysilane is phenyltriethoxysilane.

Examples of the reactive group of the second trialkoxysilane may include, but are not limited to, an alkenyl group, an epoxy group, a mercapto group, and combinations thereof. In certain embodiments, the second trialkoxysilane has an alkoxy group with a carbon number ranging from 1 to 2. For example, the second trialkoxysilane may be 3-glycidyloxypropyltrimethoxysilane (GLYMO), 3-methacryloxypropyltrimethoxysilane, (3-mercaptopropyl)trimethoxysilane, or combinations thereof.

In certain embodiments, the tetraalkoxysilane has an alkoxy group with a carbon number ranging from 1 to 2. In an exemplary embodiment, the tetraalkoxysilane is tetraethyl orthosilicate (TEOS).

According to the present disclosure, the colloidal solution may be obtained by a sol-gel process. The reaction procedures and conditions for the abovementioned hydrolysis and condensation reactions are not particularly limited, and may be suitably adjusted by one skilled in the sol-gel process according to practical requirements for the colloidal solution to be prepared.

Examples of the metal source may include, but are not limited to, an aluminum source, a zirconium source, a titanium source, and combinations thereof. The modification with the metal source may be carried out in a physical manner by, for example, mixing the metal source serving as a filler (such as aluminum oxide powders, zirconium oxide powders, titanium oxide powders, or combinations thereof) with the polysilsesquioxane mixture, so that the metal source occupies the space of the polysilsesquioxane mixture. Alternatively, the modification with the metal source may be carried out in a chemical manner by subjecting the metal source (such as an aluminum-containing chelate, a zirconium-containing chelate, a titanium-containing chelate, or combinations thereof) to complexation with the polysilsesquioxane mixture. A non-limiting example of the aluminum-containing chelate is aluminum acetylacetonate (Al(acac)₃). A non-limiting example of the zirconium-containing chelate is tetrakis(2,4-pentanedionato) zirconium (IV) (Zr(acac)₄). A non-limiting example of the titanium-containing chelate is titanium diisopropoxide bis(acetylacetonate).

In certain embodiments, the hydrophobic modifying layer has a thickness ranging from 500 nm to 1000 nm.

According to the present disclosure, the moisture barrier film further includes a multi-layered barrier unit that is disposed on the hydrophobic modifying layer and that includes at least one of an aluminum oxide layer, an aluminum-doped zinc oxide layer, and a silicon oxide layer.

In certain embodiments, the multi-layered barrier unit includes the aluminum oxide layer, the aluminum-doped zinc oxide layer, and the silicon oxide layer laminated to one another. The aluminum oxide layer may have a thickness ranging from 10 nm to 200 nm. The silicon oxide layer may have a thickness ranging from 30 nm to 200 nm. The aluminum-doped zinc oxide layer may have a thickness ranging from 10 to 150 nm. The present disclosure also provides a moisture barrier device that includes a substrate and the abovementioned moisture barrier film disposed on the substrate.

The substrate may be light-transmissible and may be made of a material with high flexibility, but is not limited thereto. Examples of the material suitable for making the substrate include, but are not limited to, polyester resin, polyacrylate resin, polyolefin resin, polycarbonate resin, polyimide resin and polylactic acid. Examples of polyester resin may include, but are not limited to, polyethylene terephthalate (PET) and polyethylene naphthalate (PEN). Example of polyacrylate resin may include, but is not limited to, polymethylmethacrylate (PMMA). Examples of polyolefin resin may include, but are not limited to, polyethylene and polypropylene. The substrate may be subjected to a surface-modifying treatment, such as oxygen plasma treatment, but is not limited thereto. The substrate has a thickness that may range from 25 μm to 250 μm, but is not limited thereto.

In addition, the present disclosure provides a method for preparing the moisture barrier device, which includes the steps of:

providing the substrate;

forming the polysilsesquioxane mixture by subjecting the first trialkoxysilane to the hydrolysis and condensation reaction with at least one of the second trialkoxysilane or the tetraalkoxysilane, followed by modifying the polysilsesquioxane mixture with the metal source to obtain the colloidal solution; and

applying the colloidal solution to the substrate and solidifying the colloidal solution, so as to form the hydrophobic modifying layer on the substrate.

In certain embodiments, the colloidal solution is applied to the substrate by a process selected from the group consisting of wet coating, spin coating, inject printing, spray coating and combinations thereof.

According to the present disclosure, the method further includes the step of forming the multi-layered barrier unit on the hydrophobic modifying layer. The aluminum oxide layer, the silicon oxide layer, and the aluminum-doped zinc oxide layer of the multi-layered barrier unit can be prepared from an aluminum oxide target, a silicon oxide target, and a aluminum-doped zinc oxide target, respectively, via a process selected from the group consisting of sputtering deposition (such as magnetron sputtering), evaporation deposition, plasma-enhanced atomic layer deposition (PEALD), plasma-enhanced chemical vapor deposition (PECVD), atmospheric pressure atomic layer deposition (APALD) and combinations thereof.

Before the present disclosure is described in greater detail, it should be noted that where considered appropriate, reference numerals or terminal portions of reference numerals have been repeated among the figures to indicate corresponding or analogous elements, which may optionally have similar characteristics.

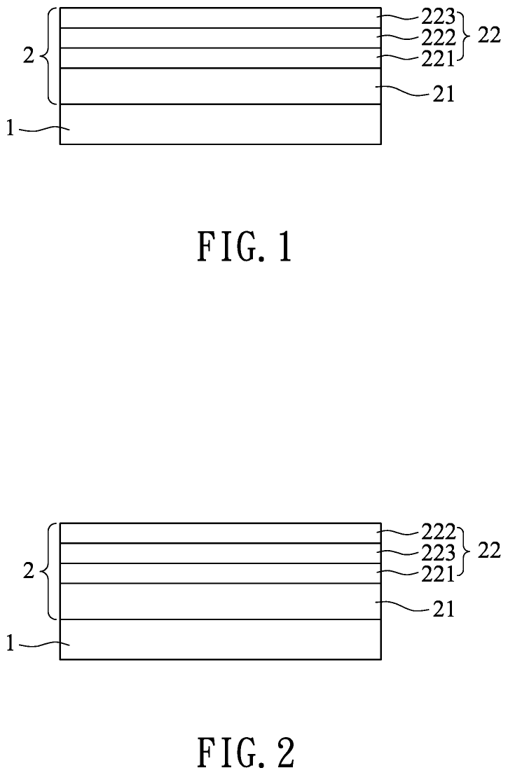

Referring to FIG. 1, a first embodiment of a moisture barrier device according to the present disclosure includes a substrate 1 and a moisture barrier film 2 disposed on the substrate 1. The moisture barrier film 2 includes a hydrophobic modifying layer 21 disposed on the substrate 1, and a multi-layered barrier unit 22 disposed on the hydrophobic modifying layer 21. The multi-layered barrier unit 22 includes the aluminum oxide layer 221, the aluminum-doped zinc oxide layer 222, and the silicon oxide layer 223 laminated to one another. Specifically, the aluminum oxide layer 221 is disposed on the hydrophobic modifying layer 21, and the aluminum-doped zinc oxide layer 222 is disposed between the aluminum oxide layer 221 and the silicon oxide layer 223.

Referring to FIGS. 2 to 6, second to sixth embodiments of moisture barrier devices according to the present disclosure respectively are shown to be similar to the first embodiment, except for the laminate configuration of the aluminum oxide layer 221, the aluminum-doped zinc oxide layer 222 and the silicon oxide layer 223.

Referring to FIG. 2, in the second embodiment of the moisture barrier device, the aluminum oxide layer 221 of the multi-layered barrier unit 22 is disposed on the hydrophobic modifying layer 21, and the silicon oxide layer 223 is disposed between the aluminum oxide layer 221 and the aluminum-doped zinc oxide layer 222.

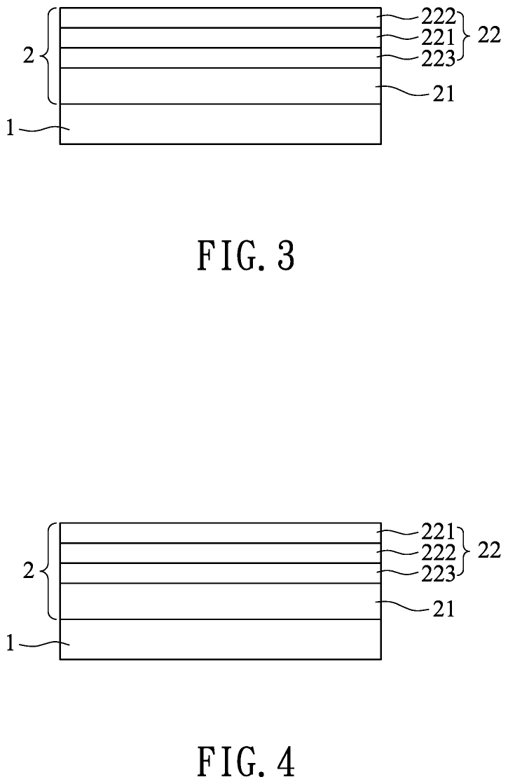

Referring to FIG. 3, in the third embodiment of the moisture barrier device, the silicon oxide layer 223 of the multi-layered barrier unit 22 is disposed on the hydrophobic modifying layer 21, and the aluminum oxide layer 221 is disposed between the silicon oxide layer 223 and the aluminum-doped zinc oxide layer 222.

Referring to FIG. 4, in the fourth embodiment of the moisture barrier device, the silicon oxide layer 223 of the multi-layered barrier unit 22 is disposed on the hydrophobic modifying layer 21, and the aluminum-doped zinc oxide layer 222 is disposed between the silicon oxide layer 223 and the aluminum oxide layer 221.

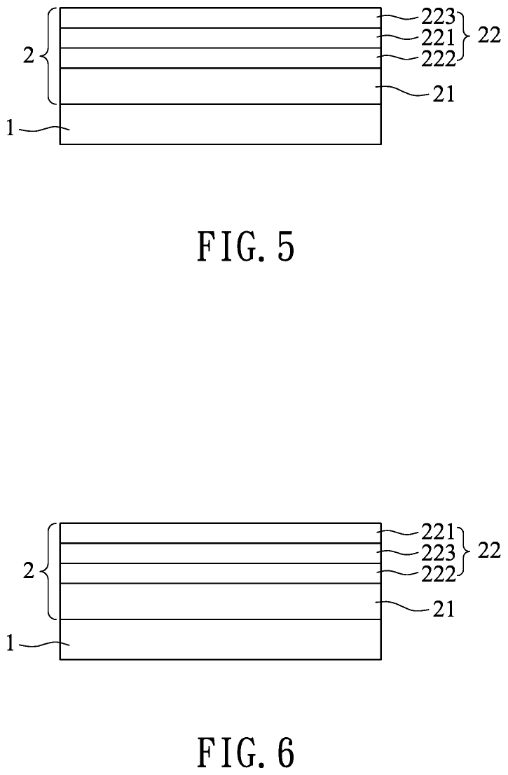

Referring to FIG. 5, in the fifth embodiment of the moisture barrier device, the aluminum-doped zinc oxide layer 222 of the multi-layered barrier unit 22 is disposed on the hydrophobic modifying layer 21, and the aluminum oxide layer 221 is disposed between the aluminum-doped zinc oxide layer 222 and the silicon oxide layer 223.

Referring to FIG. 6, in the sixth embodiment of the moisture barrier device, the aluminum-doped zinc oxide layer 222 of the multi-layered barrier unit 22 is disposed on the hydrophobic modifying layer 21, and the silicon oxide layer 223 is disposed between the aluminum-doped zinc oxide layer 222 and the aluminum oxide layer 221.

The present disclosure will be further described by way of the following examples. However, it should be understood that the following examples are intended solely for the purpose of illustration and should not be construed as limiting the present disclosure in practice.

### EXAMPLES

### Preparation of Barrier Device

### Preparative Example 1 (PE1)

### Preparation of First Polysilsesquioxane

1.8 g of deionized water and 0.05 g of hydrochloric acid having a concentration of 36.5% were added into a round-bottom flask and then mixed by stirring using a magnetic stirrer. 4 g of 3-glycidyloxypropyltrimethoxysilane (purchased from Aldrich, purity of ≥8%, abbreviated as GLYMO) and 6.102 g of phenyltriethoxysilane (purchased from Aldrich, 98%≥purity, abbreviated as PIES) were added into a sample vial and then subjected to ultrasonic vibration for 10 minutes so as to obtain a first precursor. Thereafter, the first precursor was slowly drop-added using a syringe into the round-bottom flask placed in an ice bath and then stirred to start a first hydrolysis and condensation reaction, so as to obtain a first composition. Subsequently, the round-bottom flask was taken out of the ice bath and the first composition was continuously stirred until reaching a room temperature of 25° C. After that, the first composition was subjected to a reflux reaction at 80° C. for 4 hours to complete the first hydrolysis and condensation reaction and then cooled to room temperature, thereby obtaining a first polysilsesquioxane.

### Preparation of Second Polysilsesquioxane

2.761 g of deionized water, 0.46 g of absolute ethanol, and 0.046 g of hydrochloric acid having a concentration of 36.5% were mixed by stirring in a flask. 3 g of PIES and 6.067 g of tetraethyl orthosilicate (purchased from Acros Organics, purity of 98%, abbreviated as TEOS) were added into a sample vial and then subjected to ultrasonic vibration for 10 minutes so as to obtain a second precursor. Thereafter, the second precursor was drop-added into the round-bottom flask using a pipette to start a second hydrolysis and condensation reaction, so as to obtain a second composition. Subsequently, the second composition was stirred at high speed at a room temperature of 25° C. until the second composition gradually changed from white to transparent, indicating the second hydrolysis and condensation reaction was completed, and a second polysilsesquioxane was thereby obtained.

### Preparation of Colloidal Solution

The first polysilsesquioxane was mixed with 0.11 g of aluminum acetylacetonate (purchased from Acros Organics, purity of 97%) as a metal source under stirring until the aluminum acetylacetonate was completely dissolved, and then 12 g of n-butanol (purchased from Honeywell Riedelde Haen purity of ≥9.5%) was added thereto under stirring for 20 minutes. Next, the second polysilsesquioxane was added using a pipette and then stirred for 30 minutes, after which pH was adjusted to 2.0 using a mixture of hydrochloric acid and n-butanol in a ratio of 1:1. The resultant product was continuously stirred at room temperature for 2 days (i.e., aging time was 2 days), thereby obtaining a colloidal solution of PE1, in which the first and second polysilsesquioxanes were complexed (modified) with the metal source.

### Preparation of Modifying Layer

First, a surface of a polyethylene terephthalate (PET) substrate (Manufacturer: Nan Ya Plastics Corporation; Model: CH885Y; thickness: 125 μm) was cleaned using high-pressure air, and then placed onto a coating apparatus (Manufacturer: Erichsen GmbH & Co. KG; Model: Coatmaster 510). Next, the colloidal solution obtained above was applied on the surface of the PET substrate using a syringe (injection head was equipped with a 0.22 μm filter) and then was evenly coated on the surface of the PET substrate (thickness of coating: 20 μm) using a blade coater. Thereafter, the PET substrate coated with the colloidal solution was placed in an aluminum pan, covered with aluminum foil, and baked in an oven at 60° C. for 15 minutes, 80° C. for 15 minutes, and then 105° C. for 60 minutes to solidify the colloidal solution, so as to form a modifying layer on the PET substrate, thereby obtaining a barrier device of PE1.

### Preparative Example 2 (PE2)

The procedures and conditions for preparing a barrier device of PE2 were similar to those of PE1, except that the only the first polysilsesquioxane as prepared in PE1 was used to form the modifying layer on the PET substrate.

### Preparative Example 3 (PE3)

The procedures and conditions for preparing a barrier device of PE3 were similar to those of PE1, except that only the second polysilsesquioxane as prepared in PE1 was used to form the modifying layer on the PET substrate.

### Comparative Example 1 (CE1)

The procedures and conditions for preparing a barrier device of CE1 were similar to those of PE1, except for the preparation of the colloidal solution in CE1 and the alkoxysilanes used therein.

To be specific, 7.051 g of TEOS, 8 g of GLYMO and 2.059 g of n-butanol were added into a round-bottom flask, followed by stirring with a magnetic stirrer to obtain a first mixture. 2.437 g of deionized water, 0.112 g of hydrochloric acid having a concentration of 36.5%, and 1.559 g of absolute ethanol were added to a sample vial and then stirred to obtain a second mixture. Next, the round-bottom flask containing the first mixture was placed in an ice bath, and the second mixture was slowly added into the round-bottom flask using a syringe under stirring, so as to obtain a third mixture. Thereafter, the round-bottom flask was removed from the ice bath and the third mixture was stirred at room temperature (i.e., 25° C.), so as to raise the temperature thereof to the room temperature. Subsequently, the third composition was subjected to a reflux reaction at 80° C. for 1.5 hours to complete hydrolysis and condensation reaction. Then, 1.109 g of n-butanol, 0.22 g of aluminum acetylacetonate (purchased from Acros Organics, purity of 97%) and 0.165 g of zirconium acetylacetonate (purchased from Tokyo Chemical Industry, purity of 98%) were added into the round-bottom flask, after which pH was adjusted to 2.0 using a mixture of hydrochloric acid and n-butanol in a ratio of 1:1. The resultant product was continuously stirred at the room temperature for 2 days, thereby obtaining a colloidal solution of CE1.

### Property Evaluation of the Barrier Device

### 1. Hydrophobicity

Hydrophobicity of each of the barrier devices of PE1 to PE3 and CE1 was determined by measuring a water contact angle of the modifying layer of the barrier device using a contact angle goniometer (Manufacturer: Sindatek Instruments Co., Ltd; Model No.: 100SB). The greater the water contact angle of the modifying layer, the greater the hydrophobicity of the modifying layer. On the contrary, the smaller the water contact angle of the hydrophobic modifying layer, the greater the hydrophilicity of the modifying layer. The measurement results are shown in Table 1 below.

### 2. Light Transmittance Rate

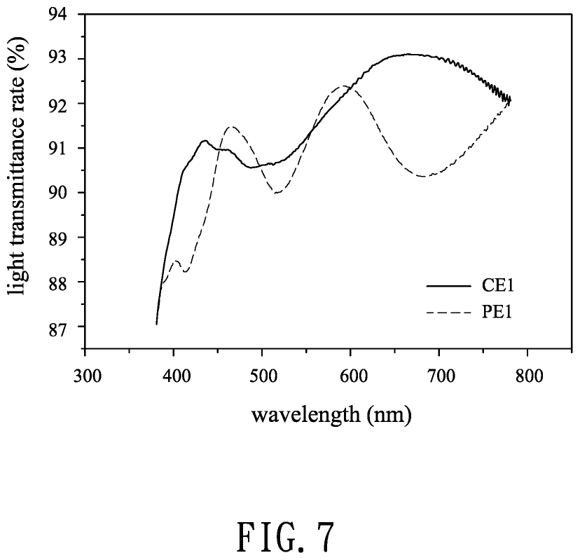

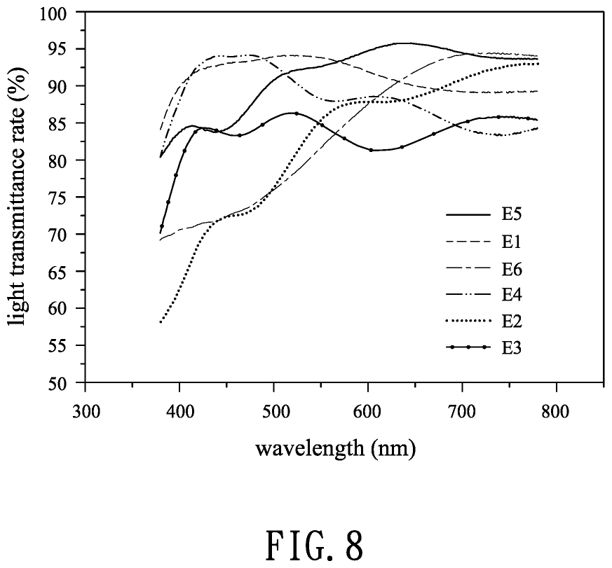

Light transmittance rate (T %) of each of the barrier devices of PE1 and CE1 was measured using an UV-Vis-NIR spectrophotometer (Manufacturer: Agilent Technologies, Inc.; Model: Cary 5000). The UV-Vis-NIR spectrophotometer was first subjected to all-optical calibration using air as background, and then each of the barrier devices was analyzed in the UV-Vis-NIR spectrophotometer under a wavelength ranging from 380 nm to 780 nm. FIG. 7 shows the light transmittance rates of each of the barrier devices determined at different wavelengths. An average value of the light transmittance rates determined at the respective one of wavelengths was also calculated and the results are shown in Table 1.

### 3. Surface Roughness

Surface roughness of the modifying layer of each of the barrier devices of PE1 to PE3 and CE1 was measured using atomic force microscopy (AFM) (Manufacturer: Park System Corp.; Model No.: XE-100) with a scanning range of 10×10 μm under a non-contact mode. The surface roughness includes mean square root roughness (Rq), arithmetic mean deviation (Ra), and maximum height of profile (Rz). The smaller the value of the surface roughness, the smoother the surface of the modifying layer. The measurement results are shown in Table 1.

### 4. Water Vapor Transmission Rate (WVTR)

A sputtering target, aluminum oxide (Manufacturer: Ultimate Materials Technology Co., Ltd., a purity of 99.99 wt %, a diameter of 2 inches and a thickness of 3 mm), was sputtered on the modifying layer of each of the barrier devices of PE1 and CE1 using radio frequency magnetron sputtering (Manufacturer: Kao Duen Technology Corp.; Model No.: R-24K08-Sputtering) under a pressure of 1 mtorr, a power of 100 W and a time period of 212 minutes, so as to form an aluminum oxide layer having a thickness of 200 nm on the modifying layer. The modifying layer and the aluminum oxide layer together form a barrier film.

The resultant barrier device was subjected to determination of water vapor transmission rate (WVTR) using a water vapor permeating instrument (Manufacturer: Ametek Mocon; Model: Mocon AQUATRAN® Model 2 G, detection limit: 5×10⁻⁵ g/m²·day). Specifically, the barrier device was mounted in a sample holder of the water vapor permeation instrument, which was maintained at 37.8° C. During measurement, one side of the sample holder was controlled to have a relative humidity of 100% using a hygrometer that was equipped in the water vapor permeation instrument, and then nitrogen gas was introduced thereinto at a flow rate of 20 sccm. Water vapor carried by the nitrogen gas from the one side of the sample holder penetrated through the barrier film, and then entered into a phosphorous pentaoxide (P₂O₅) sensor equipped at the other side of the sample holder so as to detect an amount of the water vapor permeating through the barrier film, thereby analyzing the WVTR of the barrier film of the barrier device. The lower the detected WVTR, the better the water vapor (moisture) barrier effect of the barrier film. The measurement results are shown in Table 1 below.

TABLE 1

| | Barrier device | | | | |
|---|---|---|---|---|---|
| | Modifying layer | | | | |
| | | | | T (%) | Barrier film |
| | | Water contact angle | Surface | 380 nm to | WVTR |
| | Alkoxysilane | (Hydrophobicity) | roughness | 780 nm | (g/m² · day) |
| PE1 | TEOS, GLYMO, PTES | 85.09° | Rq = 0.298 | 90.72 | 0.0232 |
| | | | Ra = 0.237 | | |
| | | | Rz = 2.307 | | |
| PE2 | GLYMO, PTES | 82.02° | Rq = 1.067 | Not | Not |
| | | | Ra = 0.853 | determined | determined |
| | | | Rz = 7.529 | | |
| PE3 | TEOS, PTES | 83.50° | Rq = 0.376 | Not | Not |
| | | | Ra = 0.298 | determined | determined |
| | | | Rz = 3.063 | | |
| CE1 | TEOS, GLYMO | 59.45° | Rq = 0.310 | 91.70 | 0.125 |
| | | | Ra = 0.244 | | |
| | | | Rz = 2.484 | | |

As shown in Table 1, as compared to CE1, the modifying layers of PE1 to PE3, which contain PIES, exhibit a higher hydrophobicity. In particular, the modifying layer of PE1 containing the polysilsesquioxane mixture further complexed (modified) with the metal source tend to create a relatively smooth surface. In addition, although PE1 has a light transmittance similar to CE1, the barrier film of PE1, through its hydrophobic modifying layer, has better water vapor barrier effect compared to that of CE1.

### Preparation of Moisture Barrier Device Having Modifying Layer and Multi-Layered Barrier Unit

### Example 1 (E1)

The moisture barrier device of E1 includes the modifying layer of PE1, which was prepared as aforesaid, and a multi-layered barrier unit sputtered on the modifying hydrophobic layer. The multi-layered barrier unit includes an aluminum oxide layer, an aluminum-doped zinc oxide layer and a silicon oxide layer which are sequentially arranged from bottom to top, and the preparation thereof are described in details as follows.

### Preparation of Aluminum Oxide Layer

A sputtering target, aluminum oxide (Manufacturer: Ultimate Materials Technology Co., Ltd., a purity of 99.99 wt %, a diameter of 2 inches and a thickness of 3 mm), was sputtered under a pressure of 1 mtorr, a power of 100 W and a time period of 80 minutes, so as to obtain an aluminum oxide layer.

### Preparation of Aluminum-Doped Zinc Oxide Layer

A sputtering target, aluminum-doped zinc oxide (Manufacturer: Ultimate Materials Technology Co., Ltd., zinc oxide and aluminum oxide of 97 wt % and 3 wt %, respectively), was sputtered under a pressure of 1 mtorr, a power of 50 W and a time period of 23 minutes, so as to obtain an aluminum-doped zinc oxide layer.

### Preparation of Silicon Oxide Layer

A sputtering target, silicon oxide (Manufacturer: Ultimate Materials Technology Co., Ltd., a purity of 99.99 wt %), was sputtered under a pressure of 1 mtorr, a power of 100 W and a time period of 36 minutes, so as to obtain a silicon oxide layer.

### Example 2 to Example 6 (E2 to E6)

The procedures and conditions for preparing each of the moisture barrier devices of E2 to E6 are similar to those of E1, except that laminate configuration of the multi-layered barrier units in E2 to E6 was different (see Table 2).

### Property Evaluation of the Moisture Barrier Device

Each of the moisture barrier devices of E1 to E6 were subjected to detections of light transmittance rate and water vapor transmission rate as described above, and subjected to determination of color value as described below.

Color value in CIELAB color space of each of the moisture barrier devices of E1 to E6 was measured using a UV-Vis-NIR spectrophotometer (Manufacturer: Agilent Technologies, Inc.; Model: Cary 5000) with a color grading software (Color). L* value represents lightness that ranges from 0 (i.e., blackness) to 100 (i.e., whiteness). A positive a* value indicates redness, and a negative a* value indicates greenness. An absolute value of a* in a range from 0 to 1 indicates the color is not visible to the human eye. A positive b* value indicates yellowness, and a negative *b value indicates blueness. An absolute value of the b* in a range from 0 to 1 indicates the color is not visible to the human eye. The measurement results are shown in Table 2.

TABLE 2

| Moisture | | | | | | |
|---|---|---|---|---|---|---|
| barrier | Laminate | T (%) | CIELAB color space | | | WVTR |
| devices | configuration | 380 nm to 780 nm | L* | a* | b* | (g/m² · day) |
| E1 | POAZS | 91.31 | 97.0939 | 0.0402 | −0.2804 | 8.612 × 10⁻³ |
| E2 | POASZ | 82.47 | 93.5096 | 0.0809 | 9.4672 | 4.567 × 10⁻³ |
| E3 | POSAZ | 83.58 | 93.5453 | −1.8870 | 0.0845 | 9.500 × 10⁻³ |
| E4 | POSZA | 88.32 | 95.5066 | 0.1330 | −3.1125 | 1.002 × 10⁻² |
| E5 | POZAS | 91.33 | 97.2006 | −0.3411 | 4.9948 | 1.221 × 10⁻² |
| E6 | POZSA | 83.82 | 92.4279 | 2.6375 | 7.2494 | 1.761 × 10⁻² |

P: PET substrate having a thickness of 125 μm
O: Hydrophobic modifying layer of PE1 having a thickness of 800 nm
Z: Aluminum-doped zinc-oxide layer having a thickness of 40 nm
S: Silicon oxide layer having a thickness of 80 nm
A: Aluminum oxide layer having a thickness of 80 nm

As shown in Table 2, each of the moisture barrier devices of E1 to E6 exhibits a good water vapor barrier effect and a high light transmittance rate. Among them, the moisture barrier devices of E1 and E5 have a light transmittance rate above 91%, and the moisture barrier devices of E1 to E3 have a water vapor transmission rate above 1×10⁻³ g/m²·day. In particular, the moisture barrier device of E1 not only has a low water vapor transmission rate (i.e., 8.612×10⁻³ g/m²·day) and a high light transmittance rate (i.e., 91.33%), but also is almost transparent and colorless to the human eye, in which L* value is 97.0939, and absolute values of a* and b* are less than 1.

In summary, by virtue of the hydrophobic modifying layer adapted to be formed on a substrate by solidification of a colloidal solution containing specific polysilsesquioxane mixture that is modified with a metal source, the moisture barrier film of the present disclosure has an excellent water vapor barrier effect and good optical properties.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A moisture barrier film adapted to be formed on a substrate, comprising:
a hydrophobic modifying layer adapted to be proximate to the substrate, and formed by solidification of a colloidal solution which includes a product obtained by subjecting a first trialkoxysilane having a hydrophobic group to a hydrolysis and condensation reaction with at least one of a second trialkoxysilane having a reactive group or a tetraalkoxysilane to form a polysilsesquioxane mixture, and subjecting said polysilsesquioxane mixture to modification with a metal source.

2. The moisture barrier film of claim 1, wherein said polysilsesquioxane mixture includes a first polysilsesquioxane and a second polysilsesquioxane, said first polysilsesquioxane being prepared by subjecting said first trialkoxysilane and said second trialkoxysilane to a first hydrolysis and condensation reaction, and said second polysilsesquioxane being prepared by subjecting said first trialkoxysilane and said tetraalkoxysilane to a second hydrolysis and condensation reaction.

3. The moisture barrier film of claim 2, wherein during the first hydrolysis and condensation reaction, said first trialkoxysilane and said second trialkoxysilane are reacted in a molar ratio ranging from 1:1 to 7:3.

4. The moisture barrier film of claim 2, wherein during the second hydrolysis and condensation reaction, said first trialkoxysilane and said tetraalkoxysilane are reacted in a molar ratio ranging from 3:7 to 1:1.

5. The moisture barrier film of claim 1, wherein said hydrophobic group of said first trialkoxysilane includes a phenyl group.

6. The moisture barrier film of claim 1, wherein said reactive group of said second trialkoxysilane is selected from the group consisting of an alkenyl group, an epoxy group, a mercapto group and combinations thereof.

7. The moisture barrier film of claim 1, further comprising a multi-layered barrier unit that is disposed on said modifying layer, and that includes at least one of an aluminum oxide layer, an aluminum-doped zinc oxide layer, and a silicon oxide layer.

8. The moisture barrier film of claim 7, wherein said multi-layered barrier unit includes said aluminum oxide layer, said aluminum-doped zinc oxide layer, and said silicon oxide layer laminated to one another, said aluminum oxide layer being disposed on said hydrophobic modifying layer.

9. The moisture barrier film of claim 8, wherein said aluminum-doped zinc oxide layer is disposed between said aluminum oxide layer and said silicon oxide layer.

10. The moisture barrier film of claim 8, wherein said silicon oxide layer is disposed between said aluminum oxide layer and said aluminum-doped zinc oxide layer.

11. The moisture barrier film of claim 7, wherein said multi-layered barrier unit includes said aluminum oxide layer, said aluminum-doped zinc oxide layer, and said silicon oxide layer laminated to one another, said silicon oxide layer being disposed on said hydrophobic modifying layer, and said aluminum oxide layer being disposed between said silicon oxide layer and said aluminum-doped zinc oxide layer.

12. The moisture barrier film of claim 7, wherein said multi-layered barrier unit includes said aluminum oxide layer, said aluminum-doped zinc oxide layer, and said silicon oxide layer laminated to one another, said silicon oxide layer being disposed on said hydrophobic modified layer, and said aluminum-doped zinc oxide layer being disposed between said silicon oxide layer and said aluminum oxide layer.

13. The moisture barrier film of claim 7, wherein said multi-layered barrier unit includes said aluminum oxide layer, said aluminum-doped zinc oxide layer, and said silicon oxide layer laminated to one another, said aluminum-doped zinc oxide layer being disposed on said hydrophobic modifying layer, and said aluminum oxide layer being disposed between said aluminum-doped zinc oxide layer and said silicon oxide layer.

14. The moisture barrier film of claim 7, wherein said multi-layered barrier unit includes said aluminum oxide layer, said aluminum-doped zinc oxide layer, and said silicon oxide layer laminated to one another, said aluminum-doped zinc oxide layer being disposed on said hydrophobic modifying layer, and said silicon oxide layer being disposed between said aluminum-doped zinc oxide layer and said aluminum oxide layer.

15. A moisture barrier device, comprising a substrate and a moisture barrier film as claimed in claim 1 that is disposed on said substrate.

16. A method for preparing a moisture barrier device, comprising the steps of:
providing a substrate;
forming a polysilsesquioxane mixture by subjecting a first trialkoxysilane having a hydrophobic group to a hydrolysis and condensation reaction with at least one of a second trialkoxysilane having a reactive group or a tetraalkoxysilane, followed by modifying the polysilsesquioxane mixture with a metal source to obtain a colloidal solution; and
applying the colloidal solution to the substrate and solidifying the colloidal solution, so as to form a hydrophobic modifying layer on the substrate.

17. The method of claim 16, wherein the step of forming the polysilsesquioxane mixture includes subjecting the first trialkoxysilane and the second trialkoxysilane to a first hydrolysis and condensation reaction to form a first polysilsesquioxane, and subjecting the first trialkoxysilane and the tetraalkoxysilane to a second hydrolysis and condensation reaction to form a second polysilsesquioxane, the polysilsesquioxane mixture including the first polysilsesquioxane and the second polysilsesquioxane.

18. The method of claim 16, wherein the step of applying the colloidal solution to the substrate is performed by a process selected from the group consisting of wet coating, spin coating, inject printing, spray coating and combinations thereof.

19. The method of claim 16, further comprising the step of forming a multi-layered barrier unit on the hydrophobic modifying layer, the multi-layered barrier unit including an aluminum oxide layer, an aluminum-doped zinc oxide layer and a silicon oxide layer laminated to one another.

20. The method of claim 19, wherein the step of forming the multi-layered barrier unit on the hydrophobic modifying layer is performed by a process selected from the group consisting of sputtering deposition, evaporation deposition, plasma-enhanced atomic layer deposition (PEALD), plasma-enhanced chemical vapor deposition (PECVD), atmospheric pressure atomic layer deposition (APALD) and combinations thereof.
